(19) United States
(12) Patent Application Publication
(10) Pub. No.: US 2026/0317906 A1
(43) Pub. Date: Oct. 15, 2026

(54) ANNULAR PUMPING FOR CHAMBER

(71) Applicant: LAM RESEARCH CORPORATION, Fremont, CA (US)

(72) Inventors: Gary B. LIND, Penn Valley, CA (US); Leonard KHO, San Francisco, CA (US); Karl Frederick LEESER, West Linn, OR (US); Atul Kumar GARG, Banda Belai (IN); Sushanth KONDI, Bangalore (IN); Arun Kumar HOSUR SHIVALINGE GOWDA, Bangalore (IN)

(21) Appl. No.: 19/117,228

(22) PCT Filed: Sep. 27, 2023
(86) PCT No.: PCT/US2023/033794

§ 371 Date: Mar. 31, 2025

Related U.S. Application Data
(60) Provisional application No. 63/413,830, filed on Oct. 6, 2022.

(51) Int. Cl. C23C 16/458; C23C 16/44; C23C 16/455

(52) U.S. Cl. CPC C23C 16/4585; C23C 16/4408; C23C 16/45544

(57) ABSTRACT

A processing chamber assembly for a substrate processing system includes a first section, a second section, and a third section. The first section defines a first volume configured to enclose a pedestal arranged within the processing chamber assembly. The first volume includes an upper portion, a middle portion, and a lower portion. The second section is disposed below the first section and defines the lower portion of the first volume. An upper surface of the second section defines a second volume radially outside of the first volume. A lower surface of the second section defines a third volume radially outside of the first volume. The third section is disposed below the second section and defines a main pumping port aligned with the third volume. First channels connect the upper portion of the first volume to the second volume. Second channels connect the second volume to the third volume.

### CROSS-REFERENCE TO RELATED APPLICATIONS

This application claims the benefit of U.S. Provisional Application No. 63/413,830, filed on Oct. 6, 2022. The entire disclosure of the application referenced above is incorporated herein by reference.

### FIELD

The present disclosure relates to showerhead, pedestal, and chamber designs for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically comprises a plurality of stations in which to perform deposition, etching, and other treatments on substrates such as semiconductor wafers. Examples of processes that may be performed on a substrate comprise a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, the substrate is disposed in the processing chamber on a substrate support such as an electrostatic chuck (ESC) or a pedestal. Process gases are introduced and, in some examples, plasma is struck in the processing chamber. The process gases are introduced using a gas distribution device, such as a showerhead.

### SUMMARY

A processing chamber assembly for a substrate processing system configured to perform bulk deposition on a substrate includes a first section, a second section, and a third section. The first section defines a first volume configured to enclose a pedestal arranged within the processing chamber assembly. The first volume includes an upper portion, a middle portion, and a lower portion. The second section is disposed below the first section and defines the lower portion of the first volume. An upper surface of the second section defines a second volume radially outside of the first volume. A lower surface of the second section defines a third volume radially outside of the first volume. The third section is disposed below the second section and defines a main pumping port aligned with the third volume. First channels connect the upper portion of the first volume to the second volume. Second channels connect the second volume to the third volume.

In other features, the upper portion of the first volume, the second volume, and the third volume provide a flow path from a deposition volume to the main pumping port radially outside of the middle portion of the first volume. The first section, the second section, and the third section are separately-machined sections coupled together. At least two of the first section, the second section, and the third section are integrally formed. The upper portion of the first volume has a stepped configuration. The first section includes a slot configured to provide access to the first volume through the first section. The first channels include upper channels connecting the upper portion of the first volume to the slot and lower channels connecting the slot to the second volume. Diameters of the first channels are varied in accordance with a location of the slot.

In other features, the upper surface of the second section includes an annular recess located radially inward of the second volume. The processing chamber assembly further includes a purge plate disposed in the lower portion of the first volume above the annular recess. The upper surface of the second section includes a raised central portion and a raised annular ledge, the annular recess is defined between the raised central portion and the raised annular ledge, and the purge plate is supported on the raised central portion and the raised annular ledge. The purge plate includes a plurality of annular slots connecting the middle portion to a volume below the purge plate within the annular recess.

In other features, the upper portion of the first volume, the middle portion of the first volume, the lower portion of the first volume, the plurality of annular slots, and the annular recess provide a flow path from a deposition volume to at least one bottom purge port extending through the second section and the third section. The at least one bottom purge port is located radially inside of the main pumping port. The processing chamber assembly further includes the pedestal.

A processing chamber assembly for a substrate processing system is configured to perform bulk deposition on a substrate. The processing chamber assembly includes a first volume configured to enclose a pedestal arranged within the processing chamber assembly. The first volume includes an upper portion, a middle portion, and a lower portion. A slot is configured to provide access to the first volume from an exterior of the processing chamber assembly. The slot is located below the upper portion of the first volume. A second volume is located radially outside of the lower portion of the first volume below the slot. First channels are located radially outside of the middle portion of the first volume. The first channels connect the upper portion of the first volume to the second volume through the slot. A third volume is located radially outside of the first volume below the second volume. A main pumping port is aligned with the third volume. The upper portion of the first volume, the second volume, and the third volume provide a flow path from a deposition volume to the main pumping port radially outside of the middle portion of the first volume.

In other features, the upper portion of the first volume has a stepped configuration. The first channels include upper channels connecting the upper portion of the first volume to the slot and lower channels connecting the slot to the second volume. Diameters of the first channels are varied in accordance with a location of the slot. The processing chamber assembly further includes an annular recess in a lower surface of the processing chamber assembly defining the lower portion of the first volume. The processing chamber assembly further includes a purge plate disposed in the lower portion of the first volume above the annular recess.

In other features, the purge plate includes a plurality of annular slots connecting the middle portion to a volume below the purge plate within the annular recess. The upper portion of the first volume, the middle portion of the first volume, the lower portion of the first volume, the plurality of annular slots, and the annular recess provide a flow path from the deposition volume to at least one bottom purge port fluidly connected to the annular recess. The at least one bottom purge port is located radially inside of the main pumping port. The processing chamber assembly further includes the pedestal.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system comprising an example carrier ring according to the present disclosure;

FIG. 2 shows an example processing chamber, showerhead, and substrate support according to the present disclosure;

FIG. 3 shows an example processing chamber assembly according to the present disclosure;

FIG. 4A is a top isometric view of an example processing chamber assembly according to the present disclosure; and

FIG. 4B is a bottom isometric view of an example processing chamber assembly according to the present disclosure.

In the drawings, reference numbers may be reused to identify similar and/or identical elements.

### DETAILED DESCRIPTION

A substrate processing tool comprises one or more process modules or chambers. For example, a multi-station module (e.g., a quad-station module (QSM)) comprises a plurality of stations in which to perform deposition, etching, and other treatments on substrates. Different processes may be performed in respective stations. Conversely, a single station module comprises only a single station.

In some examples, a nucleation process (e.g., an atomic layer deposition (ALD) nucleation step) is performed in a first station of a multi-station module while bulk fill/deposition steps are performed in other stations of the multi-station module. Optimal chamber dimensions and geometry and/or process parameters may differ for respective steps. For example, optimal chamber pressure and temperature for the nucleation step may be lower than optimal chamber pressure and temperature for bulk deposition steps. However, since the stations in a multi-station module share the same processing chamber, processing chamber conditions may not be optimal for either nucleation or bulk deposition steps.

A process module according to the present disclosure comprises components optimized for bulk deposition steps of an ALD process. For example, the process module is a single station module configured to perform bulk deposition steps separately from a nucleation step. The nucleation step may be performed in a different module or tool prior to being transferred to the process module. Accordingly, nucleation and bulk deposition steps can be performed in respective optimal process conditions. Although described with respect to bulk deposition, the principles of the present disclosure may also be applied to other types of deposition

The process module comprises a multi-part processing chamber assembly configured improve pumping uniformity within the processing chamber to reduce backside deposition on a substrate support (e.g., a pedestal). For example, the processing chamber defines multiple plenum or manifold stages to generate a uniform, annular pumping distribution for purging the processing chamber through a bottom purge port. The reduced backside deposition increases a time between required cleanings of the substrate support (e.g., by a factor of ten or more).

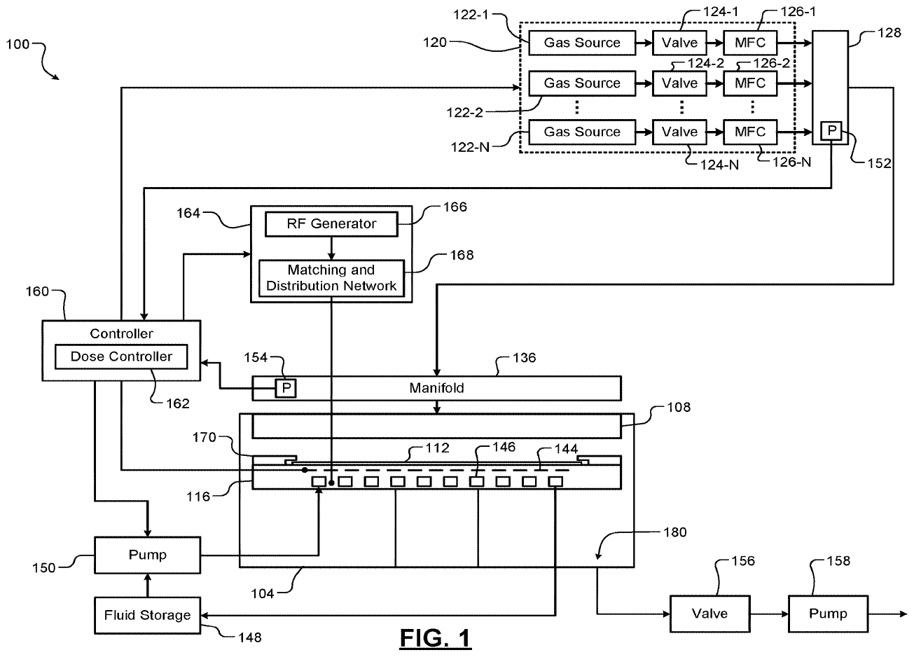

Referring now to FIG. 1, an example of a substrate processing system 100 comprising a processing chamber 104 according to the present disclosure is shown. The processing chamber 104 is comprised of an assembly of multiple sections or parts (e.g., separately machined processing chamber sections) as described below in more detail. The processing chamber 104 is configured to improve pumping uniformity during purging.

A showerhead 108 is arranged within an upper surface or portion of the processing chamber 104. A substrate 112 is arranged on a substrate support 116 (e.g., a pedestal configured for CVD and/or ALD deposition) during processing. For example, bulk deposition of an ALD process is performed on the substrate 112.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied to a manifold 136. An output of the manifold 136 is input the showerhead 108 (e.g., a multi-injector, multi-zone showerhead as described below in more detail). While the manifolds 128 and 136 are shown, a single manifold can be used.

In some examples, a temperature of the substrate support 116 may be controlled using resistive heaters 144. The substrate support 116 may comprise coolant channels 146. Cooling fluid is supplied to the coolant channels 146 from a fluid storage 148 and a pump 150. Pressure sensors 152, 154 may be arranged in the manifold 128 or the manifold 136, respectively, to measure pressure. A valve 156 and a pump 158 may be used to evacuate (i.e., purge) reactants from the processing chamber 104 and/or to control pressure within the processing chamber 104.

A controller 160 comprises a dose controller 162 that controls dosing provided by the showerhead 108. The controller 160 also controls gas delivery from the gas delivery system 120. The controller 160 controls pressure in the processing chamber and/or purging of reactants using the valve 156 and the pump 158. The controller 160 controls the temperature of the substrate support 116 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 104 as deposition processes. Accordingly, the substrate processing system 100 may comprise an RF generating system 164 configured to generate and provide RF power (e.g., as a voltage source, current source, etc.) to one of a lower electrode (e.g., a baseplate of the substrate support 116, as shown) and an upper electrode (e.g., the showerhead 108). The other one of the lower electrode and the upper electrode may be DC grounded, AC grounded or floating.

For example only, the RF generating system 164 may comprise an RF generator 166 configured to generate the RF voltage that is fed by a matching and distribution network 168 to generate plasma within the processing chamber 104 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only, transformer coupled plasma (TCP) systems, CCP cathode systems, remote microwave plasma generation and delivery systems, etc.

The substrate support 116 comprises a carrier ring 170. In some examples, an inner edge of the carrier ring 170 overlaps an outer edge of the substrate 112. In some examples, the substrate support 116 is lowered for transfer of the substrate 112 into the processing chamber 104. For example, the substrate 112 is transferred onto lift pins (not shown) that are exposed when the substrate support 116 is lowered. The substrate support 116 is then raised to engage the substrate 112 and the carrier ring 170.

In some examples, the processing chamber 104 is purged through one or more purge ports 180 (e.g., bottom purge ports) located in a bottom surface of the processing chamber 104. For example, the valve 156 and the pump 158 are controlled to selectively purge reactants downward through the processing chamber 104 and out of the purge port 180. The processing chamber 104 according to the present disclosure is configured to increase symmetry of a purge volume defined within the processing chamber 104 and facilitate a uniform, annular distribution of pumping flow as described below in more detail.

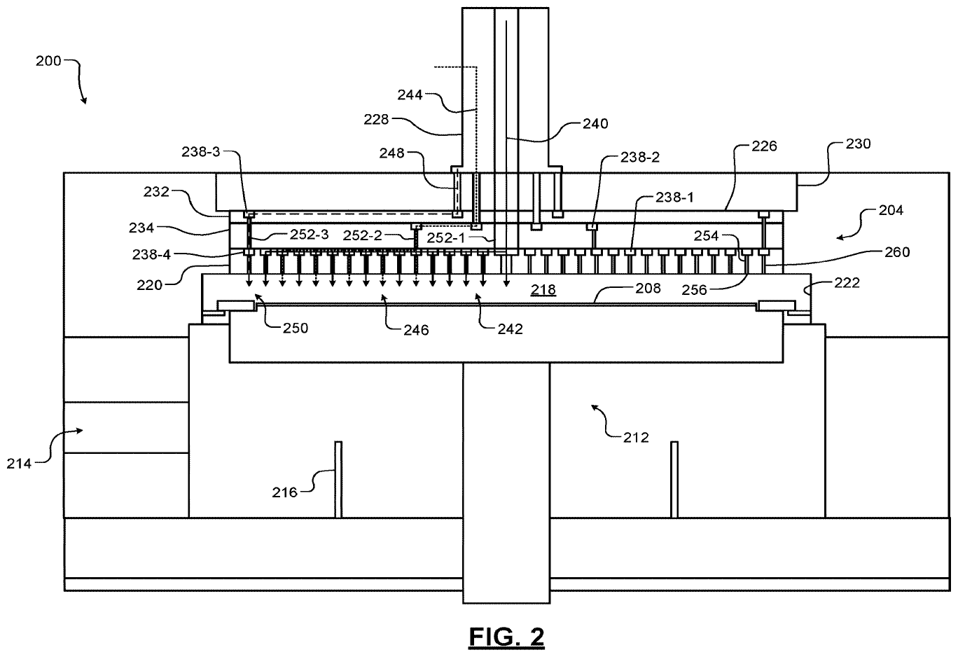

FIG. 2 shows an example processing chamber 200 comprised of a multi-part assembly according to the present disclosure. In an example, the processing chamber 200 corresponds to a station of a single station module. The processing chamber 200 is configured to supply reactants from a showerhead 204 to perform a bulk deposition step on a substrate 208 subsequent to a nucleation step performed in a different processing chamber. For example, subsequent to a nucleation step, the substrate 208 is transferred to a substrate support (e.g., a pedestal) 212 arranged within the processing chamber 200.

In one example, the substrate 208 is transferred through a slot or other opening 214 in a sidewall of the processing chamber 200 when the pedestal 212 is in a lowered position. When the pedestal 212 is in the lowered position, lift pins 216 extend above an upper surface of the pedestal 212 and the substrate 208 is placed onto the lift pins 216 (e.g., using a transfer robot). The pedestal 212 is then raised to lift and support the substate 208 in a raised position as shown in FIG. 2.

Each of the processing chamber 200, the showerhead 204, and the pedestal 212 is configured to minimize azimuthal non-symmetries in a deposition zone 218 defined between the showerhead 204 and the pedestal 212. For example, the deposition zone 218 is a symmetrically annular volume defined between a lower, substrate-facing faceplate 220 of the showerhead 204, an annular inner surface 222 of the processing chamber 200, and the pedestal 212. Further, a gap between the faceplate 220 and the pedestal 212 is minimized to maintain uniformity of process gas flow and distribution within the deposition zone 218.

The showerhead 204 is comprised of a base or head portion 226 and a stem portion 228. The stem portion 228 extends through an upper wall (e.g., a lid 230) of the processing chamber 200 to connect to the head portion 226. For example, the head portion 226 comprises the faceplate 220, a backplate 232, and a middle plate 234 disposed between the faceplate 220 and the backplate 232. In this example, the faceplate 220 functions as an upper surface of the processing chamber 200.

The faceplate 220, the backplate 232, and the middle plate 234 define at least three flow paths and respective plenums 238 within the head portion 226 to provide radial tunability and process configurability. For example, one or more plenums 238-1 are defined in an upper surface of the faceplate 220, a plenum 238-2 is defined in an upper surface of the middle plate 234, a plenum 238-3 is defined in an upper surface of the backplate 232, and a plenum 238-4 is defined in the faceplate 220 radially outside of the plenum 238-1. The plenums 238-1, 238-2, 238-3, and 238-4 are referred to collectively as plenums 238.

As shown, a first flow path (shown as solid lines/arrows) 240 supplies gases through the stem 228 and into a corresponding plenum defined in a center zone 242 of the faceplate 220. A second flow path (shown as dotted lines/arrows) 244 supplies gases through the stem 228 and into a corresponding plenum defined in a radial or middle zone 246 of the faceplate 220. A third flow path (shown as dashed lines/arrows) 248 supplies gases through the stem 228 and into a corresponding plenum defined in an outer or edge zone 250 of the faceplate 220. For example only, the first flow path 240 is routed through the stem 228 to supply gases to the center zone 242 via a center inlet 252-1, the second flow path 244 is routed through the backplate 232 and the middle plate 234 to supply gases to the middle zone 246 through a middle inlet 252-2, and the third flow path 248 is routed through the backplate 232 and the middle plate 234 to supply gases to the edge zone 250 through an edge inlet 252-3.

The faceplate 220 includes a plurality of holes 254 extending from the plenums 238 to the deposition zone 218 within the processing chamber 200. For example, gases in the first flow path 240 flow through holes 254 in the center zone 242, gases in the second flow path 244 flow through holes 254 in the middle zone 246, and gases in the third flow path 248 flow through holes 254 in the edge zone 250.

Gases supplied to the center zone 242, the middle zone 246, and the edge zone 250 can be independently controlled to either add or delete specific reactants (i.e., gases) supplied to corresponding regions of the substrate 208. For example, a gas mixture supplied to the deposition zone 218 to perform bulk deposition may include various reactive and non-reactive gases, such as argon (Ar), molecular hydrogen (H₂), tungsten hexafluoride (WF₆), molecular nitrogen (N₂), etc. Other gases and gas mixtures may be supplied in other examples, such as diborane (C₂H₆), silane (SiH₄), etc. Amounts of each of the gases supplied to the respective zones 242, 246, 250 can be controlled (e.g., using separately controllable components of a gas control system, such as the gas control system 120) to tune deposition rates and film properties in the different regions of the substrate 208. In other words, amounts of each gas supplied to each of the zones can be independently controlled.

As shown in FIG. 2, gases provided to the edge zone 250 via the third flow path 248 are provided only to outermost holes 260 in the faceplate 220. In other words, the third flow path 248 does not supply gases to the center zone 242 and the middle zone 246. For example, the holes 260 are in fluid communication with the plenum 238-3 and the plenum 238-4 defined in the edge zone 250 of the faceplate 220 but are not in fluid communication with the plenum 238-1 defined in the center zone 242 and the middle zone 246. As an example, the plenum 238-4 in the edge zone 250 is separated from the plenum 238-1 in the center zone 242 and the middle zone 246.

Conversely, the plenum 238-1 may correspond to a single plenum defined in both the center zone 242 and the middle zone 246. Accordingly, gases supplied via both the first flow path 240 and the second flow path 244 are supplied to the same plenum 238-1. The gases supplied via the first flow path 240 and the second flow path 244 are blended within the plenum 238-1 and flow through the holes 254.

The processing chamber 200 according to the present disclosure is an assembly comprised of a first section (e.g., an upper section) 264, a second section (e.g., a lower section) 268, and a third section (e.g., a bottom plate) 272. For example, the first section 264, the second section 268, and the third section 272 are separately-machined aluminum sections that are brazed together to form the processing chamber 200. The processing chamber 200 may include a fourth section (e.g., a top section) 276 configured to engage with the showerhead 204 and the lid 230 and define the deposition zone 218.

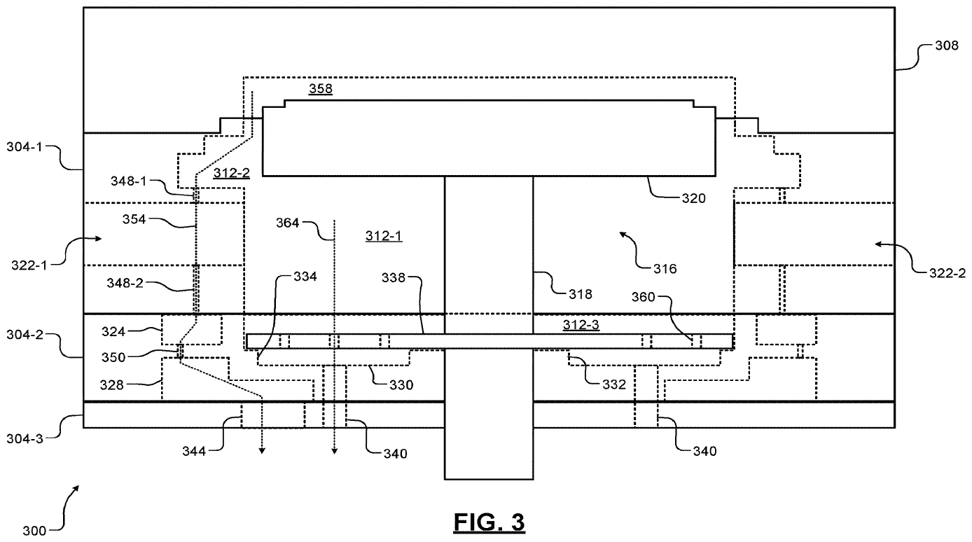

FIG. 3 shows a processing chamber assembly 300 including a first section 304-1, a second section 304-2, and a third section 304-3 (referred to collectively as sections 304) according to the present disclosure in more detail. For simplicity of illustration, some details shown in FIG. 2 (e.g., the showerhead 204, the lift pins 216, etc.) are omitted in FIG. 3. Various manifolds, plenums or interior volumes, and channels defined within the sections 304 are shown as dashed lines. Although shown as three sections (e.g., separately-machined sections that are brazed together), in other examples the assembly 300 may be comprised of fewer or more than three sections and/or formed by different manufacturing methods (e.g., additive manufacturing). A fourth section 308 (e.g., corresponding to the fourth section 276) may be disposed on the first section 304-1.

The first section 304-1 defines a generally annular plenum or volume including a middle portion 312-1 and an upper portion 312-2 (referred to collectively as, along with a lower portion 312-3, a first volume 312) around and enclosing a substrate support, such as a pedestal 316. For example, the middle portion 312-1 surrounds a stem portion 318 of the pedestal 316 below a baseplate portion 320 of the pedestal 316. A diameter of the middle portion 312-1 is generally the same as (or, as shown, slightly greater than) a diameter of the baseplate portion 320. The upper portion 312-2 surrounds the baseplate portion 320. The upper portion 312-2 may have a stepped configuration. In other words, as shown, an outer diameter of the upper portion 312-2 steps radially outward relative to the baseplate portion 320 one or more times. The upper portion 312-2 functions as a first manifold or a first level of manifolding.

The first section 304-1 may include one or more slots 322-1 and 322-2 (referred to collectively as slots 322) providing access to the first volume 312. For example, the slot 322-1 provides access for a substrate to be transferred onto the pedestal 316 as described above. Conversely, the slot 322-2 may function as a viewport to allow visual access to the first volume 312, the pedestal 316, etc.

The second section 304-2 defines a plurality of plenums or volumes including the lower portion 312-3 of the first volume 312, an annular second volume 324, and an annular third volume 328. The lower portion 312-3 and the second volume 324 are defined in an upper surface of the second section 304-2. For example, the lower portion 312-3 is contiguous with the middle portion 312-1 and surrounds the stem portion 318. The second volume 324 is located radially outside of the lower portion 312-3. The second volume 324 functions as a second manifold or second level of manifolding.

Conversely, the third volume 328 is defined in a lower surface of the second section 304-2. The third volume 328 overlaps (i.e., overlaps in a vertical direction) both the lower portion 312-3 and the second volume 324. For example, the third volume 328 has a generally “L” shaped cross-section. A horizontal portion of the third volume 328 extends radially inward below an outer region of the lower portion 312-3. A vertical portion of the third volume 328 is generally aligned with the second volume 324. The third volume 328 functions as a third manifold or third level of manifolding.

The lower portion 312-3 of the first volume 312 includes an annular recess 330. The annular recess 330 is defined in the upper surface of the second section 304-2. For example, the upper surface of the second section 304-2 includes a raised central portion 332, a raised annular ledge 334, and the annular recess 330 defined between the central portion 332 and the ledge 334.

A purge plate 338 (e.g., an annular or disc-shaped plate) is supported on the central portion 332 and the ledge 334 around the stem portion 318. Accordingly, the purge plate 338 separates the first volume 312 from a volume defined within the annular recess 330 below the purge plate 338. The annular recess 330 is in fluid communication with bottom purge ports 340 extending from the annular recess 330 through the second section 304-2 and the third section 304-3. Conversely, the third volume 328 is in fluid communication with a main pumping port 344 extending through the third section 304-3.

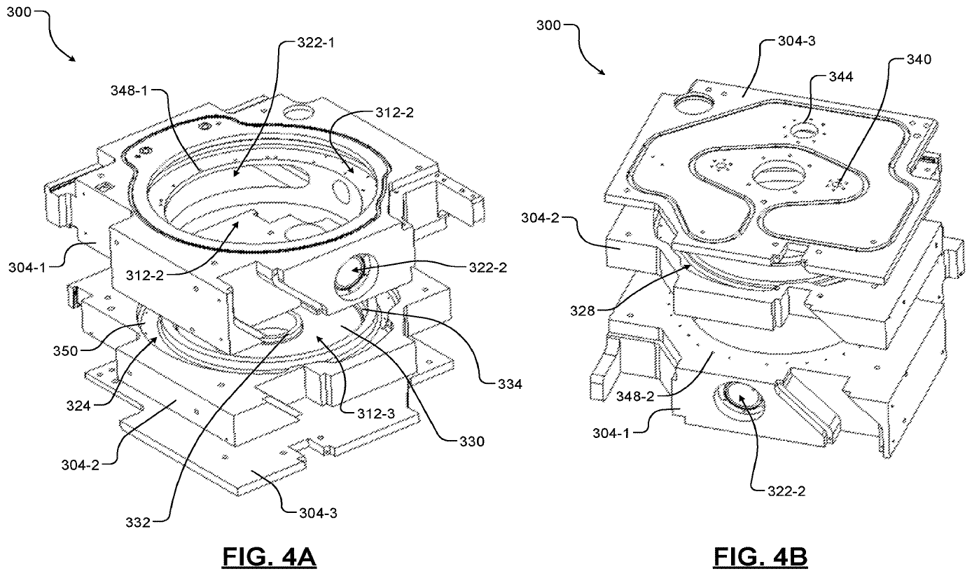

The upper portion 312-2 of the first volume 312, the second volume 324, and the third volume 328 correspond to first, second, and third levels of manifolding, respectively, to provide internal pumping passages through the first, second, and third sections 304 of the assembly 300. For example, first channels 348 (comprising upper and lower channels 348-1 and 348-2) extend between and fluidly couple the upper portion 312-2 and the second volume 324. The first channels 348 may be arranged in a circular pattern. Second channels 350 extend between and fluidly couple the second volume 324 and the third volume 328. The second channels 350 may be arranged in a circular pattern. For example, the first channels 348 and the second channels 350 include a plurality of holes (shown in more detail in FIGS. 4A and 4B) formed in the first section 304-1 and the second section 304-2.

The upper portion 312-2 of the first volume 312, the second volume 324, the third volume 328, the first channels 348, and the second channels 350 define internal pumping passages that provide a first flow path 354 for reactants to be evacuated from a deposition volume 358 above the pedestal 316 to the main pumping port 344. For example, as shown, the first flow path 354 is located radially outside of the lower portion 312-1 of the first volume 312 and the baseplate portion 320 of the pedestal 316. The components defining the first flow path 354 are configured to improve pumping uniformity and symmetry to reduce backside deposition on the pedestal 316.

As one example, the processing chamber assembly 300 may include inherently asymmetrical features such as the slots 322. In other words, if a desired symmetry of the assembly 300 corresponds to a generally uniform, circular pumping volume, features such as the slots 322 disrupt the symmetry of the pumping volume by introducing azimuthal asymmetry. For example, regions within and around the slots 322 disrupt flow of reactants downward toward the main pumping port 344, trap reactants, etc. Accordingly, the separate levels of manifolding provided by the upper portion 312-2 of the first volume 312, the second volume 324, the third volume 328, the first channels 348, and the second channels 350 are configured to compensate for asymmetry caused by the slots 322 and/or other features.

For example, each level of manifolding (i.e., the upper portion 312-2 of the first volume 312, the second volume 324, the third volume 328) is radially symmetrical and does not include any azimuthal asymmetry. In other words, each level of manifolding is uniformly circular/annular. Further, flow between the levels of manifolding is restricted by the first channels 348 and the second channels 350. Accordingly, any flow non-uniformity caused by the slots 322 or other features is corrected by regulating flow from the upper portion 312-2 using the upper channels 348-1 and regulating flow into the second volume 324 using the lower channels 348-2.

In some examples, the geometry of the upper portion 312-2 may be further configured to regulate and direct flow out of the upper portion 312-2 and into the upper channels 348-1. For example, as described above, the upper portion 312-2 has a stepped configuration.

In some examples, configurations of the first channels 348 and the second channels 350 may be varied to additionally compensate for asymmetry caused by features such as the slots 322. For example, the holes of the upper channels 348-1, the lower channels 348-2, and/or the second channels 350 above and below the slots 322 may be larger (i.e., have a larger diameter) than others of the holes. Accordingly, flow of reactants through asymmetrical regions may be increased. In other examples, the holes above and below the slots 322 may be smaller (i.e., have a smaller diameter) and flow of reactants through asymmetrical regions may be decreased. In still other examples, a density (i.e., an amount) of the holes is increased or decreased as proximity to the slots increases. In other words, an annular distribution of the holes may be varied/non-uniform to increase or decrease flow through asymmetrical regions.

The bottom purge ports 340 optionally provide additional pumping/purge flow out of the first volume 312. For example, the purge plate 338 includes a plurality of holes or annular slots 360. Accordingly, the middle portion 312-1 and the lower portion 312-3 of the first volume 312, the slots 360, the annular recess 330, and the bottom purge ports 340 define additional flow paths 364 out of the first volume 312. For example, the bottom purge ports 340 may be used to increase flow below the pedestal 316 during cleaning, such as during a remote plasma clean process. In some examples, the bottom purge ports 340 may be used along with the main pumping port 344 to purge reactants during processing.

An example of the processing chamber assembly 300 is shown in FIGS. 4A and 4B. FIG. 4A is a top isometric view of the processing chamber assembly 300 and FIG. 4B is a bottom isometric view of the processing chamber assembly 300.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform, or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A processing chamber assembly for a substrate processing system configured to perform bulk deposition on a substrate, the processing chamber assembly comprising:
a first section defining a first volume configured to enclose a pedestal arranged within the processing chamber assembly, wherein the first volume includes an upper portion, a middle portion, and a lower portion;
a second section disposed below the first section, wherein (i) the second section defines the lower portion of the first volume, (ii) an upper surface of the second section defines a second volume radially outside of the first volume, and (iii) a lower surface of the second section defines a third volume radially outside of the first volume;
a third section disposed below the second section, wherein the third section defines a main pumping port aligned with the third volume;
first channels connecting the upper portion of the first volume to the second volume; and
second channels connecting the second volume to the third volume.

2. The processing chamber assembly of claim 1, wherein the upper portion of the first volume, the second volume, and the third volume provide a flow path from a deposition volume to the main pumping port radially outside of the middle portion of the first volume.

3. The processing chamber assembly of claim 1, wherein the first section, the second section, and the third section are separately-machined sections coupled together.

4. The processing chamber assembly of claim 1, wherein at least two of the first section, the second section, and the third section are integrally formed.

5. The processing chamber assembly of claim 1, wherein the upper portion of the first volume has a stepped configuration.

6. The processing chamber assembly of claim 1, wherein the first section includes a slot configured to provide access to the first volume through the first section.

7. The processing chamber assembly of claim 6, wherein the first channels include (i) upper channels connecting the upper portion of the first volume to the slot and (ii) lower channels connecting the slot to the second volume.

8. The processing chamber assembly of claim 6, wherein diameters of the first channels are varied in accordance with a location of the slot.

9. The processing chamber assembly of claim 1, wherein the upper surface of the second section includes an annular recess located radially inward of the second volume.

10. The processing chamber assembly of claim 9, further comprising a purge plate disposed in the lower portion of the first volume above the annular recess.

11. The processing chamber assembly of claim 10, wherein the upper surface of the second section includes a raised central portion and a raised annular ledge, the annular recess is defined between the raised central portion and the raised annular ledge, and the purge plate is supported on the raised central portion and the raised annular ledge.

12. The processing chamber assembly of claim 11, wherein the purge plate includes a plurality of annular slots connecting the middle portion to a volume below the purge plate within the annular recess.

13. The processing chamber assembly of claim 12, wherein the upper portion of the first volume, the middle portion of the first volume, the lower portion of the first volume, the plurality of annular slots, and the annular recess provide a flow path from a deposition volume to at least one bottom purge port extending through the second section and the third section, wherein the at least one bottom purge port is located radially inside of the main pumping port.

14. The processing chamber assembly of claim 1, further comprising the pedestal.

15. A processing chamber assembly for a substrate processing system configured to perform bulk deposition on a substrate, the processing chamber assembly comprising:
a first volume configured to enclose a pedestal arranged within the processing chamber assembly, wherein the first volume includes an upper portion, a middle portion, and a lower portion;
a slot configured to provide access to the first volume from an exterior of the processing chamber assembly, wherein the slot is located below the upper portion of the first volume;
a second volume located radially outside of the lower portion of the first volume below the slot;
first channels located radially outside of the middle portion of the first volume, wherein the first channels connect the upper portion of the first volume to the second volume through the slot;
a third volume located radially outside of the first volume below the second volume; and
a main pumping port aligned with the third volume,
wherein the upper portion of the first volume, the second volume, and the third volume provide a flow path from a deposition volume to the main pumping port radially outside of the middle portion of the first volume.

16. The processing chamber assembly of claim 15, wherein the upper portion of the first volume has a stepped configuration.

17. The processing chamber assembly of claim 15, wherein the first channels include (i) upper channels connecting the upper portion of the first volume to the slot and (ii) lower channels connecting the slot to the second volume.

18. The processing chamber assembly of claim 17, wherein diameters of the first channels are varied in accordance with a location of the slot.

19. The processing chamber assembly of claim 15, further comprising an annular recess in a lower surface of the processing chamber assembly defining the lower portion of the first volume.

20. The processing chamber assembly of claim 19, further comprising a purge plate disposed in the lower portion of the first volume above the annular recess.

21. The processing chamber assembly of claim 20, wherein the purge plate includes a plurality of annular slots connecting the middle portion to a volume below the purge plate within the annular recess.

22. The processing chamber assembly of claim 21, wherein the upper portion of the first volume, the middle portion of the first volume, the lower portion of the first volume, the plurality of annular slots, and the annular recess provide a flow path from the deposition volume to at least one bottom purge port fluidly connected to the annular recess, wherein the at least one bottom purge port is located radially inside of the main pumping port.

23. The processing chamber assembly of claim 15, further comprising the pedestal.
